(19) United States
(12) Patent Application Publication
(10) Pub. No.: US 2019/0386253 A1
(43) Pub. Date: Dec. 19, 2019

(54) COLOR FILTER SUBSTRATE AND METHOD OF PRODUCING THE SAME AND OLED DISPLAY DEVICE

(71) Applicant: Shenzhen china Star Optoelectronics Semiconductor Display Technology Co., Ltd., Shenzhen, Guangdong (CN)

(72) Inventors: Wenjie LI, Shenzhen, Guangdong (CN); Yawei LIU, Shenzhen, Guangdong (CN)

(21) Appl. No.: 15/579,195

(22) PCT Filed: Nov. 27, 2017
(86) PCT No.: PCT/CN2017/112998

§ 371 Date: Dec. 1, 2017

(30) Foreign Application Priority Data
Oct. 12, 2017 (CN) 201710948814.1

(51) Int. Cl. H01L 51/52; H01L 27/32

(52) U.S. Cl. CPC H01L 51/5284; H01L 27/322

(57) ABSTRACT

The disclosure provides a color filter substrate and an OLED display device. The color filter substrate sets a first black matrix and a second black matrix that serve to together shelter against light, and can reduce the risk of displaying color mixing; sets a first bank in the first black matrix and a second bank in a dam layer that jointly receive and hold the printing ink required to produce a color photoresist layer, and the surface of the first bank has hydrophilicity and the surface of the second bank has hydrophobicity, and can improve evenness and film thickness uniformity of the color photoresist layer; applies the color filter substrate that can upgrade the display quality of the OLED display device; sets the dam layer and the second black matrix for replacing photo spacers in the prior art to simplify the production process.

### RELATED APPLICATIONS

The present application is a National Phase of International Application Number PCT/CN2017/112998, filed on Nov. 27, 2017, and claims the priority of China Application 201710948814.1, filed on Oct. 12, 2017.

### FIELD OF THE DISCLOSURE

The disclosure relates to the field of a display technology, and particularly to a color filter substrate and a method of producing the same and an OLED display device.

### PRIOR ART

Organic Light Emitting Diode (OLED) display device possesses a number of advantages, such as self luminous, low driving voltage, high luminous efficiency, short response time, high definition and contrast, viewing angle of nearly 180°, wide range of operating temperature, realizable flexible display and large-area full-color display, and is recognized as a new applied technology of the next-generation flat panel display in the industry.

There are several methods for the achievement of full-color display of the OLED display device.

1. Direct light-emitting by using an organic light-emitting layer having three colors consisting of red, green and blue;

2. Using a white organic light-emitting layer and a color filter (CF);

3. Using a blue organic light-emitting layer and a color conversion layer.

Currently, as for the achievement of full-color display of the OLED display device by using a white organic light-emitting layer and a color filter, it is necessary to learn from the structure of a color filter substrate in Liquid Crystal Display (LCD) when designing a color filter substrate in the OLED display device. As shown in FIG. 1, the color filter substrate 100 in the existing OLED display device generally includes a packaging cover plate 101, a black matrix (BM) 102 disposed on the packaging cover plate 101, a color photoresist layer 103 filling gaps in the black matrix 102, an over coat 104 covering the black matrix 102 and the color photoresist layer 103 and a photo spacer (PS) 105 disposed on the over coat 104, wherein the color photoresist layer 103 includes red photoresist R, green photoresist G and blue photoresist B, the photo spacer 105 is abutted against a OLED substrate 200 so as to keep a spacing between the color filter substrate 100 and the OLED substrate 200. Since the photo spacer 105 disposed on the over coat 104 would widen the spacing between the color filter substrate 100 and the OLED substrate 200, there is a risk of displaying color mixing, and the material for the photo spacer 105 is generally an organic photoresist that exhibits faint yellow and has a certain light transmission, thereby increasing the risk of displaying color mixing.

An inkjet printing (IJP) is a high efficient film-forming technology and it needs no mask plate or exposure and developing process and has higher material utilization ratio. Using the inkjet printing technology is also an innovative idea for producing the color photoresist layer. Please refer to FIGS. 2 and 3, when forming a film by using the printing method, a bank B is generally made on the substrate A to be printed for receiving printing ink and holding it. After drying and baking, the printing ink shrinks in the bank B to form the film. A contact angle between the bank B and the printing ink has a great influence on the evenness and film thickness uniformity of the formed film. If the contact angle is too large, the ink is thick in the middle and thin at two sides, as shown in FIG. 2, and if the contact angle is too small, the ink is thin in the middle and thick at two sides, as shown in FIG. 3.

It is technical problems to be solved as to how to reduce the risk of displaying color mixing of the color filter substrate in the OLED display device and how to improve the evenness and film thickness uniformity of the color photoresist layer formed by the printing method.

### SUMMARY

An object of the disclosure is to provide a color filter substrate, which can improve the evenness and film thickness uniformity of the color photoresist layer, reduce the risk of displaying color mixing, simplify the production process, and can upgrade the display quality when applying the color filter substrate into an OLED display device.

Another object of the disclosure is to provide a method for producing the color filter substrate. The color photoresist layer in the color filter substrate produced by the method has good evenness and uniform film thickness, reduced risk of displaying color mixing and simple production process.

Still another object of the disclosure is to provide an OLED display device. The color photoresist layer in the OLED display device has good evenness and uniform film thickness, reduced risk of displaying color mixing and upgraded display quality.

In order to achieve the above objects, the disclosure firstly provides a color filter substrate, including: a carrier substrate, a first black matrix disposed on the carrier substrate, a dam layer disposed on the first black matrix, a second black matrix for covering the dam layer on the first black matrix and a color photoresist;

the first black matrix having a plurality of a first bank arranged in an array manner, the dam layer having a plurality of a second bank arranged in an array manner, a second bank located above a corresponding first bank; the color photoresist layer filling in a space defined by the carrier substrate, the first bank and the second bank; and

the carrier substrate having hydrophilicity on a surface thereof, the first bank having hydrophilicity on a surface thereof and the second bank having hydrophobicity on a surface thereof; a contact angle of the first bank less than a contact angle of the second bank.

The color filter substrate further includes a protecting layer for covering the color photoresist layer, the second black matrix and the first black matrix.

Both a material for the first black matrix and a material for the second black matrix are a black organic resin or a black inorganic thin film, and a material for the dam layer is an organic resin containing fluorine element.

The black inorganic thin film is a metal oxide or a metal sulfide.

The first black matrix has a thickness of 100 to 5000 nm, the dam layer has a thickness of 1 to 10 μm and the second black matrix has a thickness of 100 to 2000 nm.

The film thickness of the color photoresist layer is the same as the thickness of the first black matrix.

The color photoresist layer may be an organic photoresist formed by dispersing a dye having three colors consisting of red, green and blue into an organic monomer, or may be a photoresist formed by dispersing quantum dot material having three colors consisting of red, green and blue into an organic solution to form quantum dot ink and then drying and baking.

The disclosure also provides a method for producing a color filter substrate, including the following steps:

step S1: providing a carrier substrate and applying hydrophilic treatment to the surface of the carrier substrate;

step S2: fabricating on the carrier substrate a first black matrix having hydrophilicity on a surface thereof; the first black matrix having a plurality of a first bank arranged in an array manner;

step S3: fabricating on the first black matrix a dam layer having hydrophilicity on a surface thereof; the dam layer having a plurality of a second bank arranged in an array manner; a second bank located above a corresponding first bank; a contact angle of the first bank less than a contact angle of the second bank;

step S4: printing out a color photoresist layer in a space defined by the carrier substrate, the first bank and the second bank by using the inkjet printing process;

step S5: fabricating on the first black matrix a second black matrix for covering the dam layer.

The method for producing a color filter substrate further includes step S6: fabricating a protecting layer on the color photoresist layer, the second black matrix and the first black matrix.

The disclosure also provides an OLED display device, including the above color filter substrate and an OLED substrate disposed opposite to the color filter substrate.

The advantageous effects of the disclosure are: in the color filter substrate provided by the disclosure, the setting of the first black matrix and the second black matrix serves to together shelter against light, and can reduce the risk of displaying color mixing; the setting of the first bank in the first black matrix and the second bank in the dam layer jointly receives and holds the printing ink required to produce the color photoresist layer, and the surface of the first bank has hydrophilicity and the surface of the second bank has hydrophobicity, and can improve evenness and film thickness uniformity of the color photoresist layer; applying the color filter substrate can upgrade the display quality of the OLED display device; the setting of the dam layer and the second black matrix for replacing the photo spacer in the prior art can simplify the production process. The method for producing the color filter substrate provided by the disclosure can fabricate the above color filter substrate so that the color photoresist layer in the color filter substrate has good evenness, uniform film thickness, reduced risk of displaying color mixing, and the production process is simple. Since the OLED display device provided by the disclosure includes the above color filter substrate, the color photoresist layer in the color filter substrate has good evenness, uniform film thickness, reduced risk of displaying color mixing, and the OLED display device has upgraded display quality.

### BRIEF DESCRIPTION OF THE DRAWINGS

In order to further understand the features and technical contents of the disclosure, the following detailed descriptions and appended drawings are hereby referred. However, the appended drawings are merely provided for reference and illustration, without any intention to be used for limiting the disclosure.

FIG. 1 is a structural cross-sectional schematic view of the existing OLED display device;

FIG. 2 is a schematic view of film thickness in a state that a contact angle is too large when forming the film by using printing methods;

FIG. 3 is a schematic view of film thickness in a state that a contact angle is too small when forming the film by using printing methods;

FIG. 4 is a structural cross-sectional schematic view of the color filter substrate of the disclosure;

FIG. 5 is a flow chart of the method for producing the color filter substrate of the disclosure;

FIG. 6 to FIG. 10 are schematic view of step S1, step S2, step S3, step S4, step S5, and step S6 in the method for producing the color filter substrate of the disclosure, respectively;

FIG. 11 is a structural cross-sectional schematic view of the OLED display device of the disclosure.

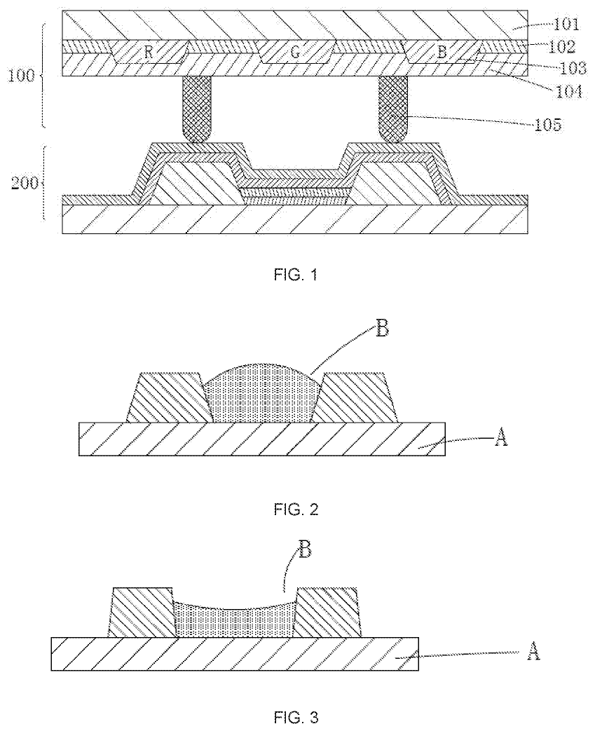

### DETAILED DESCRIPTION OF PREFERRED EMBODIMENTS

In order to further illustrate the technical means used in the disclosure and effects thereof, the description is made below in detail in conjunction with the preferred embodiments of the disclosure and the appended drawings thereof.

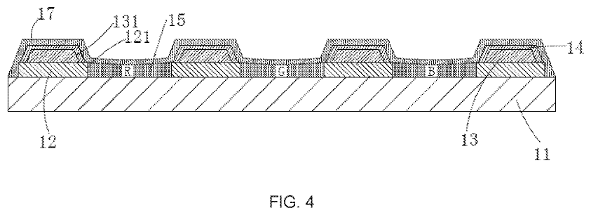

Please refer to FIG. 4, the disclosure first provides a color filter substrate, including: a carrier substrate 11, a first black matrix 12 disposed on the carrier substrate 11, a dam layer 13 disposed on the first black matrix 12, a second black matrix 14 for covering the dam layer 13 on the first black matrix 12, a color photoresist 15 and a protecting layer 17 for covering the color photoresist layer 15, the second black matrix 14 and the first black matrix 12.

The first black matrix 12 has a plurality of a first bank 121 arranged in an array manner, the dam layer 13 has a plurality of a second bank 131 arranged in the array manner, and a second bank 131 is located above a corresponding first bank 121; the color photoresist layer 15 fills in a space defined by the carrier substrate 11, the first bank 121 and the second bank 131.

A surface of the carrier substrate 11 has hydrophilicity, a surface of the first bank 121 has hydrophilicity and a surface of the second bank 131 has hydrophobicity; and a contact angle of the first bank 121 is less than a contact angle of the second bank 131, and the contact angle of the first bank 121 is relatively smaller so as to strengthen the hydrophilicity of the first bank 121, and the contact angle of the second bank 131 is relatively larger so as to strengthen the hydrophobicity of the first bank 131. The first bank 121 in the first black matrix 12 and the second bank 131 in the dam layer 13 jointly receive and hold the printing ink required to produce the color photoresist layer 15 when adopting the printing method, and particularly the inkjet printing method to produce the color photoresist layer 15. Due to the hydrophilicity of the surface of the substrate 11, the hydrophilicity of surface of the first bank 121 and the hydrophobicity of the surface of the second bank 131, the printing ink will be distributed relatively uniformly, thereby imparting good evenness and film thickness uniformity to the color photoresist layer 15 formed after drying and baking. The OLED display device can upgrade the display quality after incorporating such color filter substrate.

The first black matrix 12 and the second black matrix 12 together shelter against light, which has better light-blocking effect and can reduce the risk of displaying color mixing.

The production process may be simplified by replacing the photo spacer in the prior art with the dam layer 13 and the second black matrix 14; the spacing between the color filter substrate and the OLED substrate is decreased after the color filter substrate in the disclosure being paired with the OLED substrate, thereby further reducing the risk of displaying color mixing.

Specifically,

the carrier substrate 11 is a glass substrate or a substrate having a flexible base. The surface of the carrier substrate 11 is hydrophilically treated to be imparted hydrophilicity.

The thickness of the first black matrix 12 is preferably 100 nm to 5000 nm and may be determined based on actual needs. The material for the first black matrix 12 may be a black organic resin or a black inorganic thin film; further, the black inorganic thin film may be a metal oxide or a metal sulfide, such as copper oxide, iron oxide, manganese dioxide, ferrosoferric oxide, molybdenum sulfide, copper sulfide, and the like. In addition to light-blocking, the first black matrix 12 serves to accommodate the color photoresist layer 15 due to the setting of the first bank 121.

The thickness of the dam layer 13 is preferably 1 μm to 10 μm and may be determined based on actual needs. The material for the dam layer 13 is an organic resin containing fluorine (F) element.

The thickness of the second black matrix 14 is preferably 100 nm to 2000 nm and may be determined based on actual needs. The material for the second black matrix 14 may also be the black organic resin or the black inorganic thin film; further, the black inorganic thin film may be a metal oxide or a metal sulfide, such as copper oxide, iron oxide, manganese dioxide, ferrosoferric oxide, molybdenum sulfide, copper sulfide, and the like.

The color photoresist layer 15 includes red photoresist R, green photoresist G and blue photoresist B. The film thickness of the color photoresist layer 15 is preferably the same as the thickness of the first black matrix 12. The color photoresist layer 15 may be an organic photoresist formed by dispersing a dye having three colors consisting of red, green and blue into an organic monomer, or may be a photoresist formed by dispersing quantum dot material having three colors consisting of red, green and blue into an organic solution to form quantum dot ink and then drying and baking. The latter is preferred.

The protecting layer 17 may be a thin film made of a single layer or three layers, and is preferably a single layer thin film. The single layer thin film may be an inorganic thin film, such as dense silicon oxide, silicon nitride or aluminum oxide and the like, and has a thickness of 500 nm to 2000 nm. The three layers of thin film may be a thin film made of organic substances as a buffering layer sandwiched between the two thin films made of inorganic substances and having a thickness of 1 μm to 20 μm, such as an organic polymer resin thin film or SiOC thin film. The protecting layer 17 serves to avoid the influence of evolved gases produced during the production process of the color filter substrate on OLED in OLED substrate paired with the color filter substrate, and also serves to isolate the color filter substrate from organic filling materials for packaging OLED display device, thereby prolonging the service life of the OLED display device.

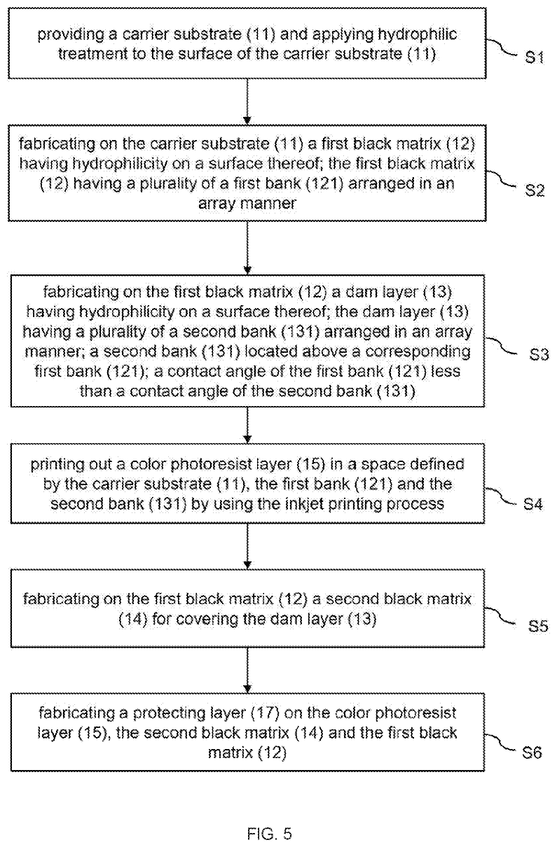

Please refer to FIG. 5, the disclosure also provides a method for producing the above color filter substrate, including the following steps.

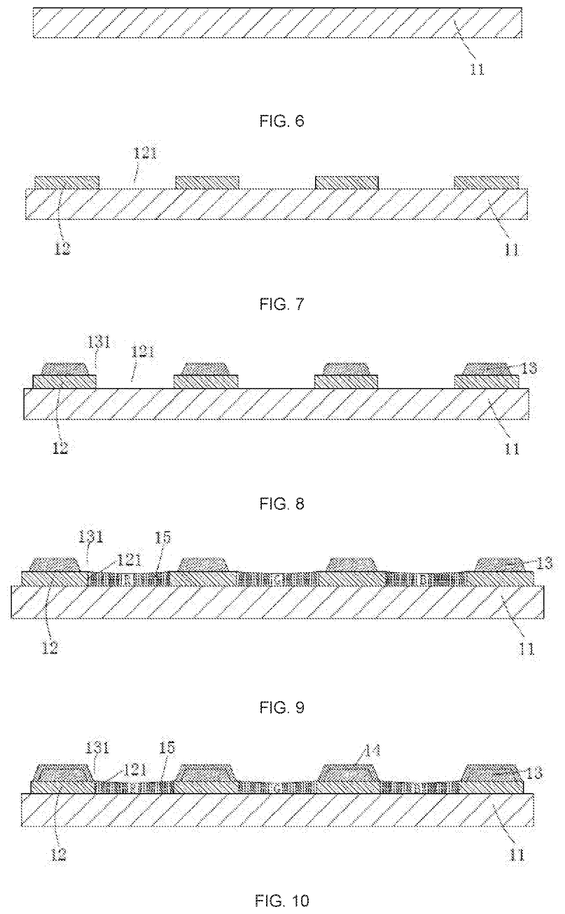

Step S1: as shown in FIG. 6, providing the carrier substrate 11 and applying hydrophilic treatment to the surface of the carrier substrate 11.

Specifically,

the carrier substrate 11 is the glass substrate or the substrate having the flexible base.

The manner of hydrophilic treatment applied to the surface of the carrier substrate 11 may be by irradiating UV or plasma onto the surface of the carrier substrate 11 for a period of time, or by modifying the surface of the carrier substrate 11 with a solution, thereby imparting hydrophilicity to the surface of the carrier substrate 11.

Step S2: as shown in FIG. 7, fabricating on the carrier substrate 11 the first black matrix 12 having hydrophilicity on a surface thereof. The first black matrix 12 has a plurality of the first bank 121 arranged in an array manner.

Specifically, the thickness of the first black matrix 12 is preferably 100 nm to 5000 nm and may be determined based on actual needs. The material for the first black matrix 12 may be the black organic resin or the black inorganic thin film; further, the black inorganic thin film may be a metal oxide or a metal sulfide, such as copper oxide, iron oxide, manganese dioxide, ferrosoferric oxide, molybdenum sulfide, copper sulfide, and the like.

If the material for the first black matrix 12 is the black organic resin, the first black matrix 12 may be fabricated by forming a thin film by means of adopting organic substances film-forming process, such as slit coating, screen printing, spin coating, inkjet printing or film casting and the like, and then subjecting to a process, such as exposure, developing and the like in the step S2.

If the material for the first black matrix 12 is the black inorganic thin film, the first black matrix 12 may be fabricated by adopting sputtering, thermal evaporation, chemical vapor deposition (CVD) or physical vapor deposition (PVD) and the like, for example, by sputtering a layer of copper sulfide to form the first black matrix 12 in the step S2.

Step S3: as shown in FIG. 8, fabricating on the first black matrix 12 the dam layer 13 having hydrophilicity on a surface thereof. The dam layer (13) has a plurality of the second bank 131 arranged in an array manner; a second bank 131 is located above a corresponding first bank 121; a contact angle of the first bank 121 is less than a contact angle of the second bank 131.

Specifically, the thickness of the dam layer 13 is preferably 1 μm to 10 μm and may be determined based on actual needs. The material for the dam layer 13 is the organic resin containing fluorine element.

The dam layer 13 may be fabricated by forming a thin film by means of adopting organic substances film-forming process, such as slit coating, screen printing, spin coating, inkjet printing or film casting and the like, and then subjecting to a process, such as exposure, developing and the like in the step S3.

Step S4: as shown in FIG. 9, printing out the color photoresist layer 15 in a space defined by the carrier substrate 11, the first bank 121 and the second bank 131 by using the inkjet printing process.

Specifically, the color photoresist layer 15 includes red photoresist R, green photoresist G and blue photoresist B. The film thickness of the color photoresist layer 15 is preferably the same as the thickness of the first black matrix 12.

The color photoresist layer 15 may be fabricated by dispersing quantum dot material having three colors consisting of red, green and blue into an organic solution to form quantum dot ink and then inkjet printing the quantum dot ink as starting material and subjecting to drying and baking in step S4.

Since the first bank 121 in the first black matrix 12 and the second bank 131 in the dam layer 13 jointly receive and hold the printing ink during the inkjet printing process, and the surface of the substrate 11 has hydrophilicity, the surface of the first bank 121 has hydrophilicity and the surface of the second bank 131 has hydrophobicity, the printing ink will be distributed relatively uniformly, thereby imparting good evenness and film thickness uniformity to the color photoresist layer 15 formed after drying and baking the printing ink.

Step S5: as shown in FIG. 10, fabricating on the first black matrix 12 the second black matrix 14 for covering the dam layer 13.

Specifically, the thickness of the second black matrix 14 is preferably 100 nm to 2000 nm and may be determined based on actual needs. The material for the second black matrix 14 may also be the black organic resin or the black inorganic thin film; further, the black inorganic thin film may be a metal oxide or a metal sulfide, such as copper oxide, iron oxide, manganese dioxide, ferrosoferric oxide, molybdenum sulfide, copper sulfide, and the like.

If the material for the second black matrix 14 is the black organic resin, the second black matrix 14 may be fabricated by forming a thin film by means of adopting organic substances film-forming process, such as slit coating, screen printing, spin coating, inkjet printing or film casting and the like, and then subjecting to a process, such as exposure, developing and the like in the step S5.

If the material for the second black matrix 14 is the black inorganic thin film, the second black matrix 14 may be fabricated by adopting sputtering, thermal evaporation, chemical vapor deposition (CVD) or physical vapor deposition (PVD) and the like, for example, by sputtering a layer of copper sulfide to form the second black matrix 14 in the step S5.

And, step S6: referring to FIG. 4, fabricating a protecting layer 17 on the color photoresist layer 15, the second black matrix 14 and the first black matrix 12. The protecting layer 17 possesses the whole surface coverage.

Specifically, the protecting layer 17 may be a thin film made of a single layer or three layers, and is preferably a single layer thin film. The single layer thin film may be an inorganic thin film, such as dense silicon oxide, silicon nitride or aluminum oxide and the like, and has a thickness of 500 nm to 2000 nm. The three layers of thin film may be a thin film made of organic substances as a buffering layer sandwiched between the two thin films made of inorganic substances and having a thickness of 1 μm to 20 μm, such as an organic polymer resin thin film or SiOC thin film.

If the protecting layer 17 is a single layer thin film made of inorganic substances, the protecting layer 17 may be fabricated by adopting chemical vapor deposition, plasma enhanced chemical vapor deposition (PECVD), atomic layer deposition (ALD) or sputtering process, for example, depositing a layer of silicon oxide by plasma enhanced chemical vapor deposition to form the protecting layer 17 in the step S6.

If the protecting layer 17 is three layers of thin film, the thin film made of inorganic substances therein may be fabricated by adopting chemical vapor deposition, plasma enhanced chemical vapor deposition, atomic layer deposition or sputtering process, while the thin film made of organic substances therein may be fabricated by adopting a process such as inkjet printing or plasma enhanced chemical vapor deposition in the step S6.

The color photoresist layer 15 in the resultant color filter substrate has good evenness and film thickness uniformity. The OLED display device can upgrade the display quality after incorporating such color filter substrate. The first black matrix 12 and the second black matrix 12 together shelter against light, and have better light-blocking effect and can reduce the risk of displaying color mixing. The production process may be simplified by replacing the photo spacer in the prior art with the dam layer 13 and the second black matrix 14.

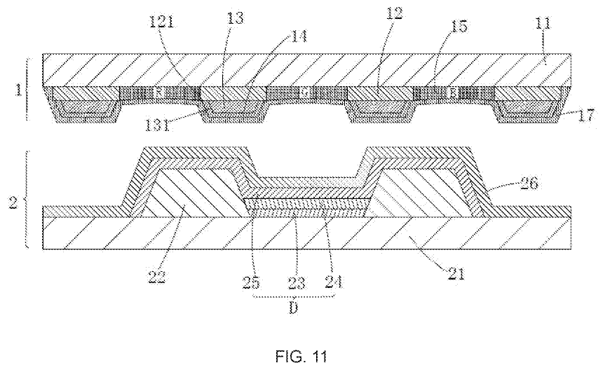

Please refer to FIG. 11, the disclosure also provides an OLED display device, including the color filter substrate 1 as shown in FIG. 4 and an OLED substrate 2 disposed opposite to the color filter substrate 1. The structure of the color filter substrate 1 is no more described repeatedly herein. In common with the prior art, the OLED substrate 2 includes a substrate 21, a pixel defining layer 22, an OLED D and a passivation layer 26, wherein the OLED D includes an anode 23, an organic functioning layer 24 and a cathode 25 stacked successively. The description is no more described extendedly herein.

In the OLED display device of the disclosure, the color photoresist layer 15 in the color filter substrate 1 has good evenness and film thickness uniformity, reduced risk of displaying color mixing, and the OLED display device has upgraded display quality.

In summary, in the color filter substrate provided by the disclosure, the setting of the first black matrix and the second black matrix serves to together shelter against light, and can reduce the risk of displaying color mixing; the setting of the first bank in the first black matrix and the second bank in the dam layer jointly receives and holds the printing ink required to produce the color photoresist layer, and the surface of the first bank has hydrophilicity and the surface of the second bank has hydrophobicity, and can improve evenness and film thickness uniformity of the color photoresist layer; applying the color filter substrate can upgrade the display quality of the OLED display device; the setting of the dam layer and the second black matrix for replacing the photo spacer in the prior art can simplify the production process. The method for producing the color filter substrate provided by the disclosure can fabricate the above color filter substrate so that the color photoresist layer in the color filter substrate has good evenness, uniform film thickness, reduced risk of displaying color mixing, and the production process is simple. Since the OLED display device provided by the disclosure includes the above color filter substrate, the color photoresist layer in the color filter substrate has good evenness, uniform film thickness, reduced risk of displaying color mixing, and the OLED display device has upgraded display quality.

As for the above, a person skilled in the art can make various corresponding modifications and variants according to the technical solution and technical idea of the disclosure, and all these modifications and variants shall fall within the scope of protection of the claims of the disclosure.

What is claimed is:

1. A color filter substrate, comprising: a carrier substrate, a first black matrix disposed on the carrier substrate, a dam layer disposed on the first black matrix, a second black matrix for covering the dam layer on the first black matrix and a color photoresist;
the first black matrix having a plurality of a first bank arranged in an array manner, the dam layer having a plurality of a second bank arranged in an array manner, a second bank located above a corresponding first bank; the color photoresist layer filling in a space defined by the carrier substrate, the first bank and the second bank; and
the carrier substrate having hydrophilicity on a surface thereof, the first bank having hydrophilicity on a surface thereof and the second bank having hydrophobicity on a surface thereof; a contact angle of the first bank less than a contact angle of the second bank.

2. The color filter substrate according to claim 1, further comprising a protecting layer for covering the color photoresist layer, the second black matrix and the first black matrix.

3. The color filter substrate according to claim 1, wherein both a material for the first black matrix and a material for the second black matrix are a black organic resin or a black inorganic thin film, and a material for the dam layer is an organic resin containing fluorine element.

4. The color filter substrate according to claim 3, wherein the black inorganic thin film is a metal oxide or a metal sulfide.

5. The color filter substrate according to claim 1, wherein the first black matrix has a thickness of 100 to 5000 nm, the dam layer has a thickness of 1 to 10 μm and the second black matrix has a thickness of 100 to 2000 nm.

6. The color filter substrate according to claim 1, wherein the film thickness of the color photoresist layer is the same as the thickness of the first black matrix.

7. The color filter substrate according to claim 1, wherein the color photoresist layer is an organic photoresist formed by dispersing a dye having three colors consisting of red, green and blue into an organic monomer, or is a photoresist formed by dispersing quantum dot material having three colors consisting of red, green and blue into an organic solution to form quantum dot ink and then drying and baking.

8. A method for producing a color filter substrate, comprising the following steps:
step S1: providing a carrier substrate and applying hydrophilic treatment to the surface of the carrier substrate;
step S2: fabricating on the carrier substrate a first black matrix having hydrophilicity on a surface thereof; the first black matrix having a plurality of a first bank arranged in an array manner;
step S3: fabricating on the first black matrix a dam layer having hydrophilicity on a surface thereof; the dam layer having a plurality of a second bank arranged in an array manner; a second bank located above a corresponding first bank; a contact angle of the first bank less than a contact angle of the second bank;
step S4: printing out a color photoresist layer in a space defined by the carrier substrate, the first bank and the second bank by using the inkjet printing process; and
step S5: fabricating on the first black matrix a second black matrix for covering the dam layer.

9. The method for producing a color filter substrate according to claim 8, further comprising step S6: fabricating a protecting layer on the color photoresist layer, the second black matrix and the first black matrix.

10. An OLED display device, comprising a color filter substrate according to claim 1 and an OLED substrate disposed opposite to the color filter substrate.
